(19) United States
(12) Patent Application Publication
(10) Pub. No.: US 2017/0032604 A1
(43) Pub. Date: Feb. 2, 2017

(54) Wires replacing transistors enabling light speed

(71) Applicant: Rashad Zaguia, Ksar Hellal (TN)

(72) Inventor: Rashad Zaguia, Ksar Hellal (TN)

(21) Appl. No.: 14/809,365

(22) Filed: Jul. 27, 2015

(51) Int. Cl. G07C 13/00; H03K 19/21

(52) U.S. Cl. CPC G07C 13/00; H03K 19/21; G06Q 2230/00

(57) ABSTRACT

Verification constraint as a mean of simplification and optimization.

Verification Function simplification to wires.

Verifiability as a state corruption reducer.

Majority vote function, approximation function or data formatting function, as a supplement to verification function, allowing access to universal logic possibilities.

### BACKGROUND OF THE INVENTION

I tried as a computer engineer to respond to the following question:

If it is easy to check that a solution to a problem is correct, is it also easy to solve the problem?

Formulated by Stephen Cook and Leonid Levin in 1971.

My main help is a decision I took in front of my self to no longer lie.

It stabilized logic and increased my performance.

It is incompatible with hacking and crime in general.

### BRIEF SUMMARY OF THE INVENTION

It is about trying to make super calculators and circuitry with any conductor (or fiber optics). It avoids or reduces rare earth resources usage of classical circuitry.

It simplifies which would help simulations and optimization of complex problems. Verified optimums results are known in economy for being efficient for solving money crisis. It also offers alternatives to quantum computers.

### BRIEF DESCRIPTION OF THE SEVERAL VIEWS OF THE DRAWING

FIG. 0: Circuitry showing how if constrained to {xor, xnor} (verification) doors then verification is equal to implementation.

FIG. 1: Circuitry showing how to connect 3 verification doors together in order to have a 3 input output pins door. Any 2 pins can be chosen to be inputs and the third would be the output.

FIG. 2: Circuitry showing how to make an approximation of {and,or} doors.

FIG. 3: 3 wires making an xor door (the idea is more in the encoding).

FIG. 4: A mechanical system demonstrating how to format the inputs correctly for xor “processors or circuitry”. Classical circuitry using transistors could also be used. the idea is more on the encoding.

FIG. 5: Tubes with characteristics that would make the approximation effect in FIG. 2 disappear.

FIG. 6: Example use of TripleXor shown in FIG. 1 to make a universal door like a nand.

### DETAILED DESCRIPTION OF THE INVENTION

The number of binary logical doors of I=inputs and O=outputs are 2̂(O*2̂I) logical doors. For verifying one of those logical doors we can use a logical door of I+O inputs and 1 output. The verification logical doors are 2̂(1*2̂(I+O)) logical doors.

Verification logical doors are not equal to implementation logical doors.

And there for: P is not equal to NP unless we use verification only to implement. The verification function that tells whether 2 digits are the same or not is the following:

| input0 | input1 | output |
|---|---|---|
| 0 | 0 | 1 |
| 0 | 1 | 0 |
| 1 | 0 | 0 |
| 1 | 1 | 1 |

Which is known in classical computer engineering as an xnor.

If we combine the 3 columns 3?=6 combinations the function would stay the same. Please notice that there is also the xor that flips the 0 and 1 and do have the same characteristics.

xor can be made with xnor:
xor(i0,i1)=xnor(0,xnor(i0,i1))

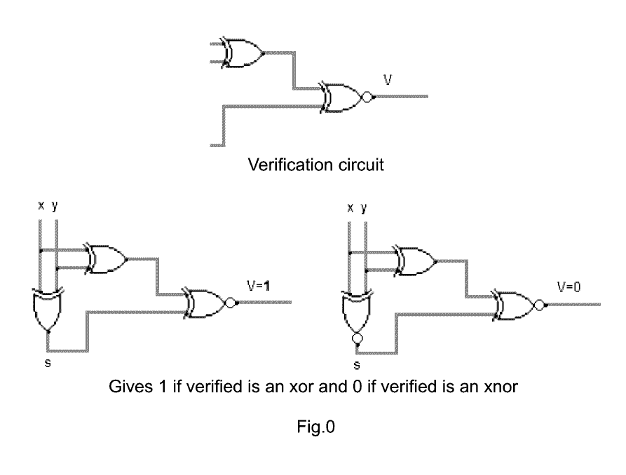

So P equals NP if we constrain, focus and capitalize effort on implementing any using xnors only. See: FIG. 0

At the beginning I could make with xnors only 2̂I programs. The choice of the maker of the program is equal to the choice of the user. From a decay I could pick only 1 possibility the rest were determinations of that choice. By a decay I meant a usage of a digit. Examples (tables):

| A | B | C | D | 1 | S | |
|---|---|---|---|---|---|---|
| 0 | 0 | 0 | 0 | 1 | 1 | odd then using 1 |
| 0 | 0 | 0 | 1 | 1 | 0 | even then using D, 1 |
| 0 | 0 | 1 | 0 | 1 | 0 | even then using C, 1 |
| 0 | 1 | 0 | 0 | 1 | 0 | even then using B, 1 |
| 1 | 0 | 0 | 0 | 1 | 0 | even then using A, 1 |
| | | | | | | S = D xor C xor B xor A xor 1 |
| A | B | C | D | 1 | S | |
| 0 | 0 | 0 | 1 | 1 | 0 | even then using D, 1 |
| 0 | 0 | 1 | 1 | 1 | 1 | odd then using C, D, 1 |
| 0 | 1 | 1 | 0 | 1 | 1 | odd then using B, C, 1 |
| 1 | 0 | 0 | 1 | 1 | 1 | odd then using A, D, 1 |
| | | | | | | S = D xor C xor B xor A xor 1 |

| A | B | C | D | S | |
|---|---|---|---|---|---|
| 0 | 0 | 0 | 1 | 0 | even then not using |
| 0 | 0 | 1 | 0 | 1 | odd then using C |
| 0 | 1 | 0 | 0 | 1 | odd then using B |
| 1 | 0 | 0 | 0 | 1 | odd then using A |
| | | | | | S = C xor B xor A |

Many thinks I could not make. I was stuck and that was for too long.

The possibility of sorting in (n*log 2(n)), sorting column of digits per column of digits attempt of realization with xors allowed me having an idea. 3 pins common to 3 xors as follows:

pin0=xor0(pin1,pin2)
pin1=xor1(pin0,pin2)
pin2=xor2(pin0,pin1)

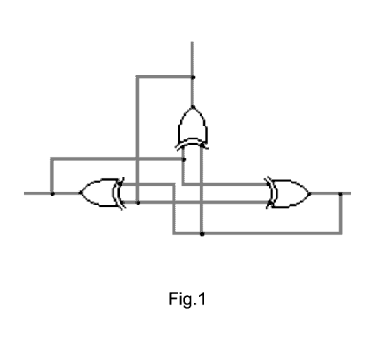

### See FIG. 1

Was not posing a short circuit problem due to the combinatorial characteristics of the xor door. As a consequence entering 2 pins would determine the third one and pins would be inputs and outputs. Using this special door I'm naming triplexor we could create universal doors. A nand as an example, defined as

pin0=nand(pin1,pin2) would be:
pin0=triplexor(1,0)
pin0=triplexor(1,pin1)
pin0=triplexor(1,pin2)

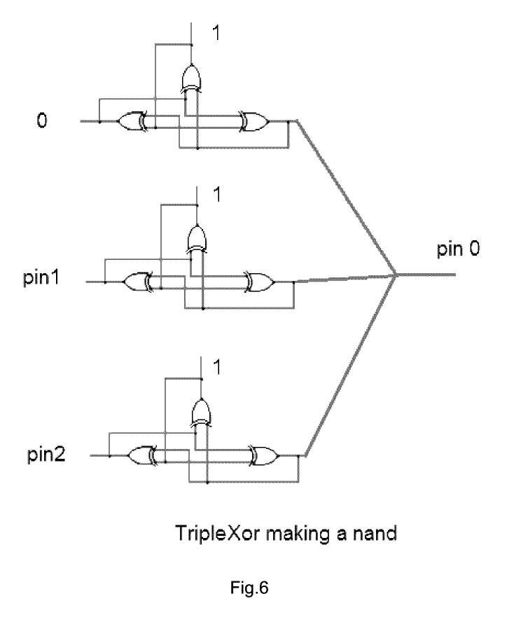

### See FIG. 6

“None lying democracy can govern logic.”

programs made with xors could run both ways where there is not much difference between inputs and outputs. See: FIG. 1 “A competitor to quantum computers”.

During my work heat seemed to make p and np closer unlike cold.

Results: triplexor with the help of wires connection function can make any program.

Simple watching people can act on them along with watchers will line.

As verifier influences verified.

The structure of the organization or system we are in, influences our logical abilities.

Elections organizers should allow voters to verify their votes in terms of quantity and content.

What to keep in mind is that buying votes is more difficult then changing the end result. Verifying votes, taxing, properties and budget by public with encrypting to preserve confidentiality is possible,

Here is an example of implementation:

The address of the voter determines the bureau where he or she is going to vote.

If he or she want to change the location of voting the ID showing the person address must be updated.

At voting location 3 powers must be present often are an executive worker a legislative worker and a judiciary worker.
First the executive: Verifies the ID and gives the last water bill of its address.
Second the legislative: Has 2 bags of numbers.

A bag A having numbers that match the ids number format.

A bag B having numbers that match the water bills number format.

A number in one of those 2 bags is available in 2 copies attached to each other.

The legislative worker picks a random number from bag A.

Keeps a copy of the number where he or she writes the id number and gives to the voter the other copy without writing on it any think.

The legislative worker also picks a random number from bag B.

Keeps a copy of the number where he or she writes the water bill number and amount and gives to the voter the other copy writing on it the amount of the water bill only. (amounts should be rounded at low resolution as taxing since issuing the water bill)
Third the judiciary:

Has 2 bags of numbers.

A bag A having numbers that match the ids number format.

A bag B having numbers that match the water bills number format.

A number in one of those 2 bags is available in 2 copies attached to each other.

The judiciary worker picks a random number from bag A.

Keeps a copy of the number where he or she writes the legislative id number and gives to the voter the other copy without writing on it any think.

The judiciary worker also picks a random number from bag B.

Keeps a copy of the number where he or she writes the legislative water bill number and amount and gives to the voter the other copy writing on it the amount of the legislative water bill only.

Voter votes in secret puts the 2 judiciary numbers on the envelope shows them to the judiciary worker and puts the envelope in ballot.

He or she can copy by hand the judiciary numbers before getting out.

The voter at voting location can verify the following:

The number of votes each power counted.

How many voted from her or his address seeing the judiciary number of the water bill.

The total of water bills in that bureau.

The total of bills in all bureaus.

Her or his vote and In case of a mistake the 3 powers can be gathered to fix it and that is for a limited delay until the Destruction of all links kept by powers between numbers.

The same technique of verification can be applied to the revenue of the nations or organization to verify the total of money.

Instead of a water bill we could have the spending of an address.

On the subject of drinkable water

Saturation of water is independent of what is being solved in it.

Many do have undrinkable salty water and removing sugar is easier then removing salt.

Add sugar to salty water until saturation.

Remove the deposits.

Redo the operation until water totally sweet and not salty.

3 functions can be made without transistors, simple wires instead.

The 3 functions {and,or,not} can make any function and there for a computer.

(note: this was the first approximation and sharply require a repeater after several layers of doors unlike the previously demonstrated)

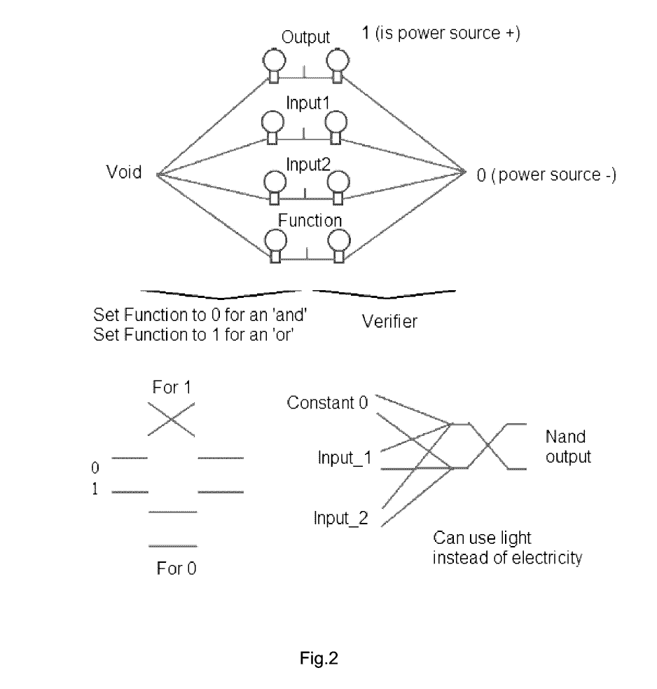

### See: FIG. 2.

Tubes with characteristics that would make the approximation effect in FIG. 2 disappear. Those tubes may be materials that do have a none linear resistance to light or to electricity. They may also be lenses. An implementation of an and and an or.

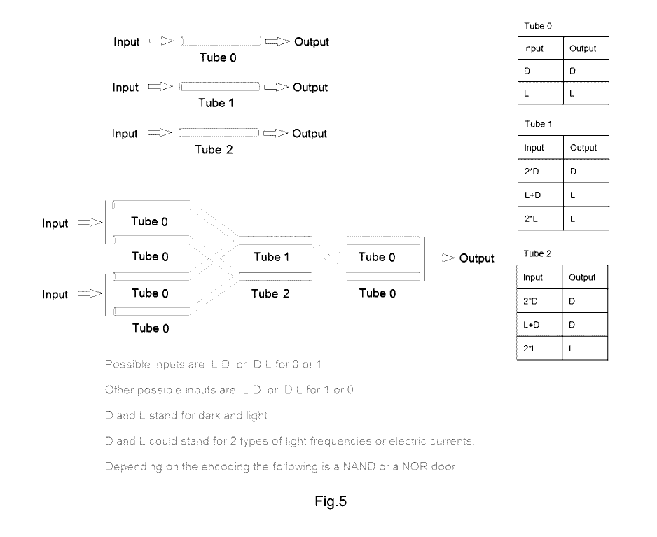

### See FIG. 5

Let: L be a luminosity.
0 be the set of even multiples of L {0L, 2L, 4L, 6L, . . . }
1 be the set of odd multiples of L {1L, 3L, 5L, 7L, . . . }

Then: 0 mixed with 0 would give 0
0 mixed with 1 would give 1
1 mixed with 0 would give 1
1 mixed with 1 would give 0

Which is an xor that can run at the speed of photons or electrons. (light verification)

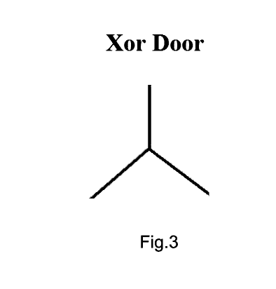

### See: FIG. 3.

It is a bit hard to make 2 distinct inputs fall in different decays while counting. (See: table above)

So a solution is to do that at inputs and here is an example of that (simplified):

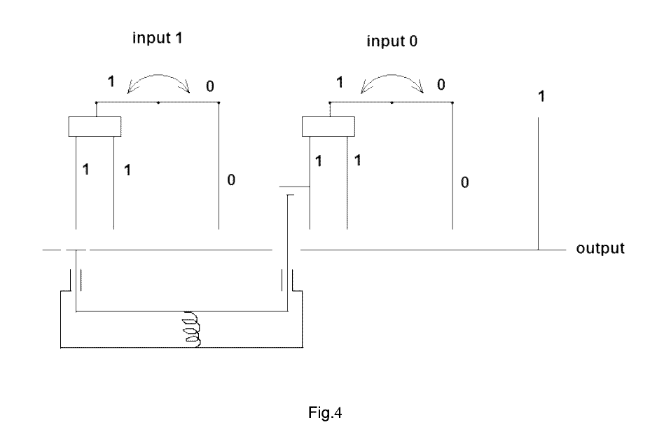

### See: FIG. 4.

What I claim is:

1) The triplexor door made with 3 xor doors.

2) Elections organizers allowing people verifying their secret voting results instead of asking them to believe trusted people.
Remarque: This claim is with will in the opposite direction then making it impossible for some to buy.
Remarque: “Secret voting” means making it a bit difficult to reveal a person voting decision to another without consent.
Public allowed to verify state country or organization revenue while keeping source secret, protecting privacy.
In this matter around developing countries I also claim replacing a solved in a solution with another one using the saturation point characteristic of the liquid.

3) FIG. 2: The wires circuitry showing how to make an approximation of {and,or} doors.
Remarque: Lamps could be resistances.
The not door (flipping wires after encoding {0,1} as {01,10} regardless of which encoding is for which input and of what encoded 1 and what encoded 0 in the {01,10} encoding).
The logical door demonstrated in FIG. 5
FIG. 3: 3 wires making an xor door (the idea is more an idea of a set encoding to make a logical door with wires).
FIG. 4: A mechanical system demonstrating how to format the inputs correctly for xor “processors or circuitry”.
Classical circuitry using transistors could also be used.
The idea is more of encoding many inputs properly for xors since input.
The idea of sending a super calculator in a satellite around the sun since heat or closure to the sun ease calculus.
